(19) United States
(12) Patent Application Publication
(10) Pub. No.: US 2015/0107764 A1
(43) Pub. Date: Apr. 23, 2015

(54) PROCESS FOR PRODUCING ADHESIVE SHEET HAVING SINGULATED ADHESIVE LAYER, PROCESS FOR PRODUCING WIRING SUBSTRATE USING THE ADHESIVE SHEET, METHOD OF MANUFACTURING SEMICONDUCTOR EQUIPMENT, AND EQUIPMENT FOR PRODUCING ADHESIVE SHEET

(71) Applicants: Masaya Katayama, Otsu-shi (JP); Hiroyuki Niwa, Otsu-shi (JP); Toshihisa Nonaka, Otsu-shi (JP)

(72) Inventors: Masaya Katayama, Otsu-shi (JP); Hiroyuki Niwa, Otsu-shi (JP); Toshihisa Nonaka, Otsu-shi (JP)

(73) Assignee: TORAY INDUSTRIES, INC., Chuo-ku, Tokyo (JP)

(21) Appl. No.: 14/234,339

(22) PCT Filed: Jun. 26, 2013
(86) PCT No.: PCT/JP2013/067459

§ 371 Date: Jan. 22, 2014

(30) Foreign Application Priority Data
Jul. 3, 2012 (JP) 2012-149074

(51) Int. Cl. C09J 7/02; H05K 3/30; B32B 38/10; B32B 37/12; B32B 38/00; H01L 21/50; B32B 37/00

(52) U.S. Cl. CPC C09J 7/02; H01L 21/50; H05K 3/305; B32B 37/025; B32B 37/12; B32B 38/0004; B32B 38/10
USPC 156/248; 156/249; 156/510

(57) ABSTRACT

Provided is a process for producing an adhesive sheet having a singulated adhesive layer (b) on a carrier film (a), comprising the following steps in the order mentioned:
Step A: cutting an adhesive film having a carrier film (a), an adhesive layer (b), and a cover film (c) in the order mentioned locally only at the adhesive layer (b) and the cover film (c) by means of local half-cutting;
Step B: peeling only the cover film (c) at unwanted parts of the adhesive film;
Step C: applying adhesive tape to the side of the cover film (c) of the adhesive film; and
Step D: peeling the adhesive layer (b) at unwanted parts and the cover film (c) at desired parts of the adhesive film together with the adhesive tape.

Also provided are a process for producing an adhesive sheet comprising a singulated adhesive disposed at a specific position, and equipment for producing an adhesive sheet.

### TECHNICAL FIELD

The present invention relates to a process for producing an adhesive sheet comprising a singulated adhesive layer disposed at a specific position.

### BACKGROUND ART

In electronic materials, when mounting various parts such as a semiconductor chip on a wiring substrate, thermosetting adhesives (known as a die attach film (DAF) and a non-conductive film (NCF)) are often used.

In recent years, flip chip assembly has been used for mounting a semiconductor chip on a wiring substrate.

### PRIOR ART DOCUMENTS

### Patent Documents

In conventional flip chip assembly, after a semiconductor chip is flip-chip assembled on a wiring substrate, a resin is applied to the periphery of the semiconductor chip, and by capillarity, the liquid sealing resin is filled into a space beneath the semiconductor chip and serves as an adhesive (Patent Document 1).

Further, a pre-sealing technique has been developed, comprising forming an uncured sealing resin on a wiring substrate in advance before mounting a semiconductor chip, and pressing bumps of the semiconductor chip into the sealing resin to thereby flip-chip assemble and seal the semiconductor chip (Patent Document 2).

Further, a method comprising applying a resin film onto a wiring substrate using a mask has been proposed (Patent Document 3).

On the other hand, when an adhesive sheet comprising a singulated adhesive disposed at a specific position is used, a wiring substrate comprising an adhesive disposed at a specific position can be produced by aligning the adhesive sheet and a wiring substrate and transferring the adhesive from the adhesive sheet to the wiring substrate, and a method using half-cutting is a common method for producing such an adhesive sheet comprising a singulated adhesive disposed at a specific position (Patent Documents 4, 5, and 6).

Patent Document 1: JP 11-256012 A

Patent Document 2: JP 2011-207998 A

Patent Document 3: JP 2010-251346 A

Patent Document 4: JP 2009-84442 A

Patent Document 5: JP 2010-45070 A

Patent Document 6: JP 2008-282945 A

### SUMMARY OF THE INVENTION

### Problems to be Solved by the Invention

In the pre-sealing techniques disclosed in Patent Document 1 and Patent Document 2, a liquid resin or an uncured adhesive film is applied to a wiring substrate before mounting a semiconductor chip to thereby form an uncured adhesive on the wiring substrate. During this process, air bubbles may be entrained into the liquid resin or the adhesive. The air bubbles in the resin can cause poor connection or an insulation short circuit. In addition, using an adhesive film requires a technique for applying the adhesive film with positional accuracy.

The method using a mask disclosed in Patent Document 3 is highly versatile because it is able to deal with changes, for example, in design of a wiring substrate by changing mask design. However, level difference between parts covered by the mask and parts not covered and deformation of the mask itself can cause variation in application position, which is problematic. In addition, when a larger mask is used, processing error or bending of the mask itself may occur, and, therefore, the method is not suitable for mass-producing a single design.

The usual half-cutting methods disclosed in Patent Documents 4, 5, and 6 are designed for a material comprising a tough adhesive layer, which alone is able to withstand tension, conveyance, and the like, and cannot be applied to a material comprising a brittle adhesive layer, which alone cannot withstand tension, conveyance, or the like.

In view of the problems above, the present invention relates to a process for producing an adhesive sheet comprising a singulated adhesive layer disposed at a specific position. In particular, the present invention provides an effective method for producing an adhesive sheet comprising a brittle adhesive layer.

### Means for Solving the Problems

To solve the problems described above, the process for producing an adhesive sheet having a singulated adhesive layer of the present invention has the following constitution:

A process for producing an adhesive sheet having a singulated adhesive layer (b) on a carrier film (a), comprising the following steps in the order mentioned:

Step A: cutting an adhesive film having a carrier film (a), an adhesive layer (b), and a cover film (c) in the order mentioned locally only at the adhesive layer (b) and the cover film (c) by means of local half-cutting;
Step B: peeling only the cover film (c) at unwanted parts of the adhesive film;
Step C: applying adhesive tape to the side of the cover film (c) of the adhesive film;

and

Step D: peeling the adhesive layer (b) at unwanted parts and the cover film (c) at desired parts of the adhesive film together with the adhesive tape.

The term “unwanted parts” herein refers to parts that will be peeled off and not remain finally in the adhesive sheet.

The process for producing a wiring substrate using the adhesive sheet of the present invention has the following constitution:

A process for producing a wiring substrate, comprising: aligning the surface on the side of an adhesive layer (b) of an adhesive sheet obtained by the above production process with the surface on the side of wiring of a wiring substrate, forming a laminate comprising the adhesive sheet and the wiring substrate by vacuum lamination or vacuum press, and then removing an carrier film (a) of the adhesive sheet.

The method of manufacturing semiconductor equipment of the present invention has the following constitution:

A method of manufacturing semiconductor equipment, comprising mounting a semiconductor device on a wiring substrate obtained by the process for producing a wiring substrate described above.

The equipment for producing an adhesive sheet of the present invention has the following constitution:

Equipment for producing an adhesive sheet comprising a half-cutting apparatus, a cover film peeling apparatus, an adhesive tape applying apparatus, and an adhesive tape peeling apparatus in the order mentioned.

In the process for producing an adhesive sheet having a singulated adhesive layer of the present invention, the carrier film (a) preferably has a two-layer structure that can be peeled at the lamination interface.

In the process for producing an adhesive sheet having a singulated adhesive layer of the present invention, the adhesive tape preferably has a carrier film (a′) and an adhesive layer (b′), the carrier film (a′) being made of a polyolefin.

In the process for producing an adhesive sheet having a singulated adhesive layer of the present invention, the adhesive tape preferably has a thickness of 10 to 40 μm.

In the process for producing an adhesive sheet having a singulated adhesive layer of the present invention, in the peeling of the step D, a bending angle of the adhesive tape (θ₁) and a bending angle of the carrier film (a) (θ₂) preferably satisfy the following expressions (I) and (II):

|θ₁|<|θ₂| (I)

|θ₁|+|θ₂|<60° (II).

### Effects of the Invention

According to the production method of the present invention, an adhesive sheet comprising a singulated adhesive layer disposed at a specific position can be produced. In particular, the production method of the present invention is suitable for producing an adhesive sheet that comprises a brittle adhesive layer and requires support by a carrier.

### BRIEF DESCRIPTION OF THE DRAWINGS

FIG. 1 illustrates the adhesive sheet of the present invention comprising a singulated adhesive layer (b) disposed at a specific position;

FIG. 2 illustrates edges used for the half-cutting of the present invention.

FIG. 3 is a cross-sectional view of the adhesive film of the present invention after half-cutting;

FIG. 4 illustrates unwanted parts in peeling the cover film (c) of the present invention;

FIG. 5 illustrates the adhesive film of the present invention after peeling the cover film (c);

FIG. 6 is a cross-sectional view of the adhesive film of the present invention after half-cutting, wherein a carrier film having a two-layer structure is used;

FIG. 7 is a schematic view of the step D of the present invention;

FIG. 8 illustrates the adhesive sheet of the present invention wherein an adhesive layer (b) is present on a carrier film (a) in succession;

FIG. 9 illustrates an adhesive sheet cut into a strip;

FIG. 10 illustrates an example of the step A (cutting an adhesive film having a carrier film (a), an adhesive layer (b), and a cover film (c) in the order mentioned locally only at the adhesive layer (b) and the cover film (c) by means of local half-cutting) of the present invention; (1) is a side view, and (2) is a top view;

FIG. 11 illustrates an example of the step B (peeling only the cover film (c) at unwanted parts of the adhesive film) of the present invention;

FIG. 12 illustrates an example of the step C (applying adhesive tape to the side of the cover film (c) of the adhesive film) the present invention;

FIG. 13 illustrates an example of the step D (peeling the adhesive layer (b) at unwanted parts and the cover film (c) at desired parts of the adhesive film together with the adhesive tape) of the present invention;

FIG. 14 is a cross-sectional view of the adhesive film of the present invention after peeling unwanted parts, wherein a carrier film having a two-layer structure is used;

FIG. 15 is a plan view (1) and a cross-sectional view (2) of a substrate having 8.7-mm square open recesses; and

FIG. 16 is a plan view (1) and a cross-sectional view (2) illustrating how a singulated adhesive layer is formed at the bottom of a substrate having 8.7-mm square open recesses.

### DESCRIPTION OF EMBODIMENTS

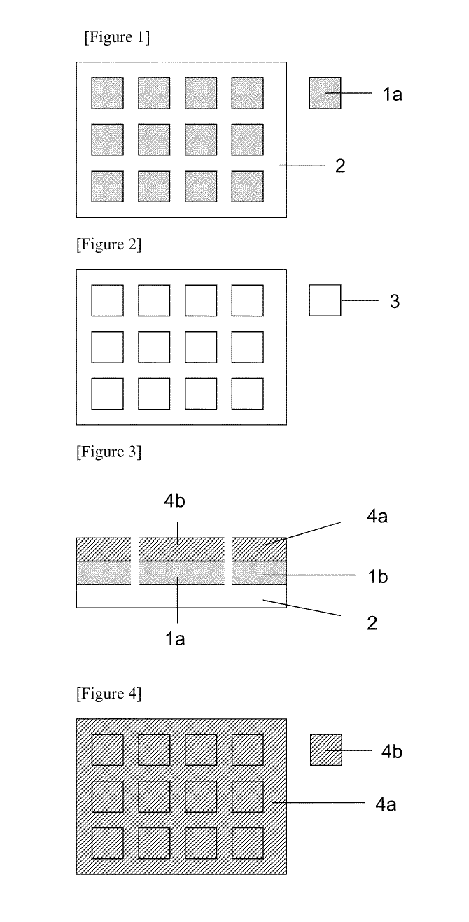

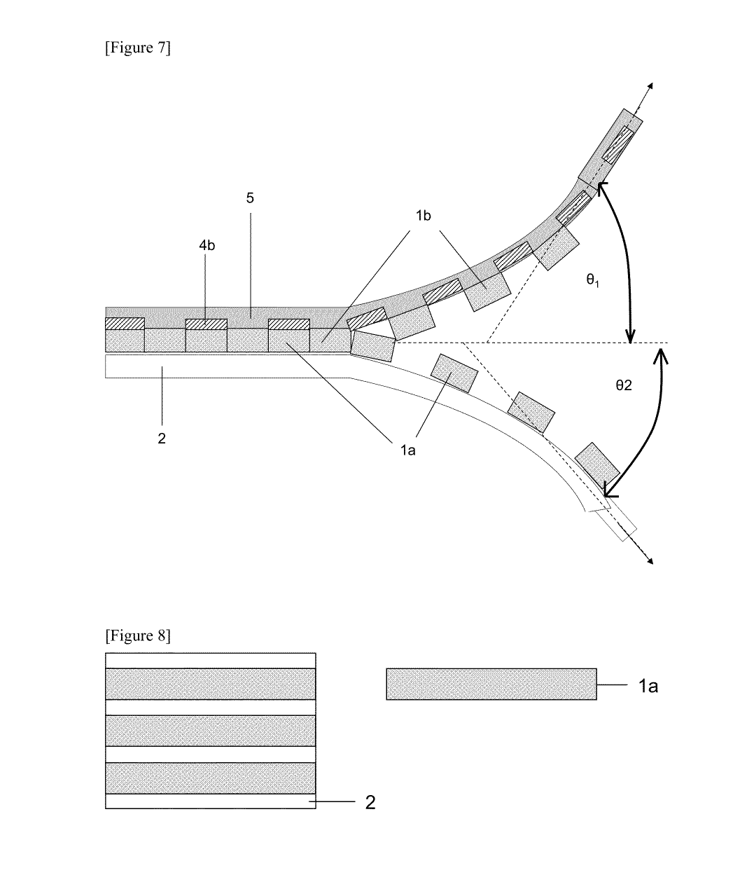

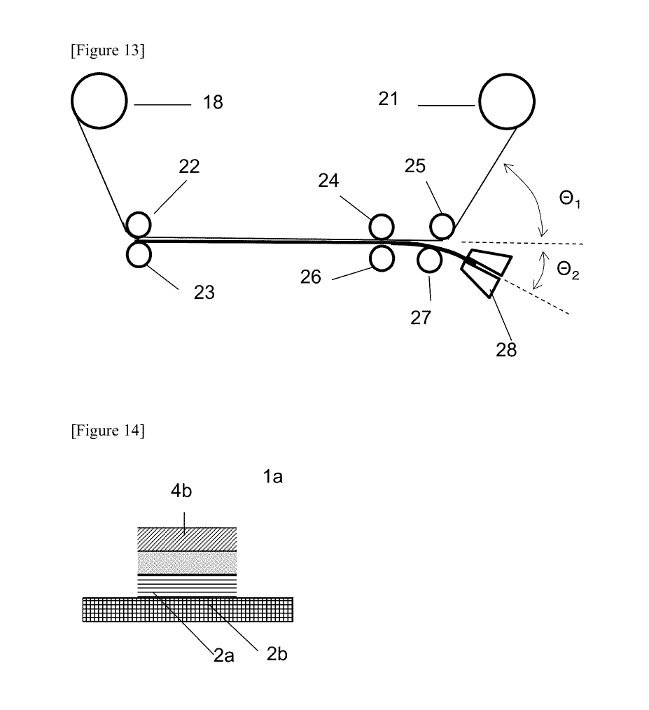

The embodiments of the present invention will now be described with reference to FIG. 1 to FIG. 13.

The present invention is a process for producing an adhesive sheet having a singulated adhesive layer (b) on a carrier film (a), comprising the following steps in the order mentioned:

Step A: cutting an adhesive film having a carrier film (a), an adhesive layer (b), and a cover film (c) in the order mentioned locally only at the adhesive layer (b) and the cover film (c) by means of local half-cutting;
Step B: peeling only the cover film (c) at unwanted parts of the adhesive film;
Step C: applying adhesive tape to the side of the cover film (c) of the adhesive film; and
Step D: peeling the adhesive layer (b) at unwanted parts and the cover film (c) at desired parts of the adhesive film together with the adhesive tape.

Each of these steps will be described in detail below.

The adhesive film used in the present invention is required to comprise at least a carrier film (a), an adhesive layer (b), and a cover film (c) in the order mentioned. Material for the carrier film (a) and the cover film (c) is not critical, and any material such as polyethylene terephthalate (PET), polyethersulfone, polyimide, polyethylene (PE), and polyvinyl acetate (PVA) can be used. A laminate formed by laminating a film on paper or the like may be used. Surface treatment with a release agent may optionally be performed in order to adjust the adhesion to the adhesive layer (b), and a film whose peel force is reduced by UV irradiation or the like may be used. The thicknesses of both the carrier film (a) and the cover film (c) are not critical, and they are preferably 10 to 200 μm, more preferably 20 to 40 μm. When the thicknesses are 10 to 200 μm, the adhesive layer (b) can be retained more sufficiently because stiffness required for conveyance during the process is sufficient, and there is no difficulty in bending or the like because the stiffness will not be too strong. The cover film (c) is preferably thinner than the carrier film (a). This is because in peeling in the step D mentioned below, peeling can be easily performed when the stiffness at the side of the carrier film (a) is stronger. Further, a film having a two-layer structure that can be peeled at the interface can also be used as the carrier film (a).

The composition of the adhesive layer (b) of the present invention is not critical, and any sheet can be used which is formed from a thermosetting or photocurable resin such as an epoxy resin, oxetane resin, or bismaleimide resin, a thermoplastic resin such as a phenoxy resin, polyethersulfone, polyamide-imide, or polyimide, or a mixture thereof. From the standpoint of insulation reliability or reliability to temperature cycle, the adhesive layer (b) may contain fillers. Examples of the fillers that can be used include inorganic particles such as silica, silicon nitride, alumina, aluminum nitride, titanium oxide, titanium nitride, and barium titanate, and organic particles such as rubber and resin.

The adhesive layer (b) of the present invention may be brittle at normal temperature, may have high fluidity at a high temperature, and may have a melt viscosity at 100° C. of 3,000 Pa·s or lower. An adhesive layer (b) having a melt viscosity at 100° C. of 3,000 Pa·s or lower has high fluidity at a high temperature and can be suitably used, for example, for embedding of a circuit pattern, but such an adhesive layer (b) is brittle in most cases. According to the process for producing an adhesive sheet of the present invention, an adhesive sheet can be suitably produced even if the adhesive layer (b) has a melt viscosity at 100° C. of 3,000 Pa·s or lower.

Such an adhesive layer (b) is used, for example, for a non-conductive film (NCF) for semiconductor assembly. This is because the NCF requires fine embedding of wiring and needs to be fluidized by heating to be low-viscosity. In return for such characteristics, the adhesive layer (b), however, is brittle at normal temperature, and the adhesive layer (b) alone often cannot withstand punching, cutting, conveyance, and the like. However, the process for producing an adhesive sheet of the present invention provides a good adhesive sheet because the carrier film (a) is used when cutting and the like are carried out.

The adhesion between the adhesive layer (b) and the carrier film (a) is not critical, but is preferably less than 30 N/m at 25° C. When the adhesion between the adhesive layer (b) and the carrier film (a) is less than 30 N/m at 25° C., the step D (peeling the adhesive layer (b) at unwanted parts and the cover film (c) at desired parts of the adhesive film together with the adhesive tape) mentioned below can be carried out efficiently.

The adhesion between the adhesive layer (b) and the cover film (c) is not critical, but is preferably less than 30 N/m at 25° C. and lower than the adhesion between the adhesive layer (b) and the carrier film (a). When the adhesion between the adhesive layer (b) and the cover film (c) is less than 30 N/m at 25° C., the step B (peeling only the cover film (c) at unwanted parts of the adhesive film) and the step D (peeling the adhesive layer (b) at unwanted parts and the cover film (c) at desired parts of the adhesive film together with the adhesive tape) mentioned below can be carried out efficiently. When the adhesion between the adhesive layer (b) and the cover film (c) is lower than the adhesion between the adhesive layer (b) and the carrier film (a), unintended peeling and the like at the adhesive layer (b) can be prevented. The term “unintended peeling” as used herein refers to a phenomenon where peeling occurs not at a desired interface but at an undesired interface.

An example of the process for producing the adhesive film used in the present invention is described below. First, materials of the adhesive layer (b); resins, fillers, and various additives, and solvents are mixed by stirring to prepare a varnish or paste, which is applied to a base film. Examples of application methods include roll coating and slit coating. The base film may be of any material such as polyethylene terephthalate (PET), polyethersulfone, and polyimide. After the application, drying is optionally performed. To protect the adhesive coated surface, any protective film may be applied after the application or after the drying. The protective film may be of any material, and for example, a polyethylene terephthalate (PET) film, a polyethylene (PE) film, and a polyvinyl acetate (PVA) film are suitable. Surface treatment with the same release agent is optionally performed. One of the base film and the protective film is used as a carrier film (a), and the other as a cover film (c). There is no restriction on which film is used as a carrier film (a).

The step A is cutting an adhesive film having a carrier film (a), an adhesive layer (b), and a cover film (c) in the order mentioned locally only at the adhesive layer (b) and the cover film (c) by means of local half-cutting. Examples of methods of half-cutting include, but are not limited to, pressing using a pinnacle die, rolling, and the like. In half-cutting, it is necessary to press edges from the side of the cover film (c) such that the edges penetrate the cover film (c) and the adhesive layer (b) but does not penetrate the carrier film (a). For example, when producing an adhesive sheet comprising a singulated adhesive layer (b) disposed at a specific position as shown in FIG. 1, edges having a shape as shown in FIG. 2 is used for half-cutting. The cross-section of an adhesive film after half-cutting is shown in FIG. 3.

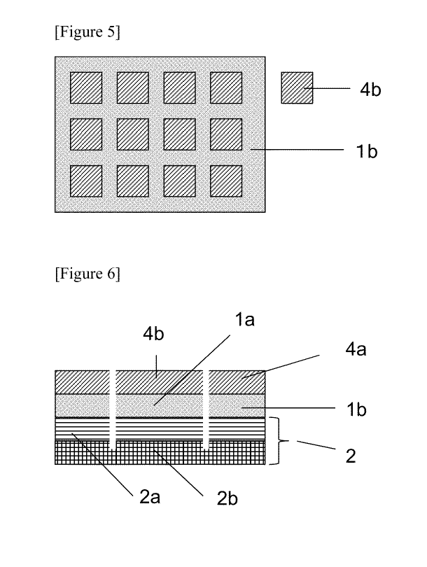

The step B is peeling only the cover film (c) at unwanted parts of the adhesive film after half-cutting. For example, when producing an adhesive sheet comprising a singulated adhesive layer (b) disposed at a specific position as shown in FIG. 1, the region denoted by 4a in FIG. 4 is the cover film (c) at unwanted parts, and only this part is peeled. Examples of methods of peeling include pull-up of the cover film (c). The angle of peeling is not critical, but is preferably 45° to 90°. Such an angle allows peeling without the unintended peeling or the like of the adhesive layer (b). After peeling the cover film (c), the adhesive layer (b) is exposed at the unwanted parts as shown in FIG. 5.

The step C is applying adhesive tape to the side of the cover film (c) of the adhesive film. Adhesive tape is applied over the whole surface of the adhesive film in the state shown in FIG. 5. Examples of methods of applying adhesive tape include, but are not limited to, lamination by pressing with a roll or the like.

The adhesive tape preferably has a carrier film (a′) and an adhesive layer (b′). As material for the carrier film (a′), polyolefins can preferably be used because they have great flexibility. Through the use of such a film having great flexibility, chipping and rupture of the adhesive layer (b′) upon peeling can be more readily prevented.

The thickness of the carrier film (a′) is preferably 25 μm or less, more preferably 15 μm or less, because rupture of the adhesive layer (b′) upon peeling the adhesive layer (b′) will not readily occur. In view of handleability, the thickness of the carrier film (a′) is preferably not less than 3 μm.

The total thickness of the adhesive tape is not critical, but is preferably 10 to 40 μm. When the total thickness is in this range, chipping and the like at the adhesive layer (b) upon peeling can be reduced while ensuring conveyance properties.

The step D is peeling the adhesive layer (b) at unwanted parts and the cover film (c) at desired parts of the adhesive film together with the adhesive tape. By removing the adhesive layer (b) at unwanted parts and the cover film (c) at desired parts, an adhesive sheet of interest as shown in FIG. 1 can be obtained in which the singulated adhesive layer (b) is located on the carrier film (a).

A film having a two-layer structure that can be peeled at the interface is used as the carrier film (a); in the half-cutting in the step A, the upper layer of the two layers which is in contact with the adhesive is completely cut, and the lower layer of the two layers which is not in contact with the adhesive layer is incompletely cut; and the peeling of unwanted parts in the step D is carried out at the interface between the two layers, whereby an adhesive sheet as shown in FIG. 2 can be obtained in which the singulated adhesive layer (b) is located on the carrier film (a). In the step D, to facilitate the peeling at the interface between the two layers, it is preferable to select materials such that the peel strength between the two layers is lower than the peel strength at the interface between the adhesive layer and the upper layer of the carrier film.

An adhesive sheet with a structure as shown in FIG. 6 can preferably be used when applying singulated adhesive to a recessed area, and can more preferably be used when a recess is deep or when a recess space has a high aspect ratio, i.e., the depth of the recess is larger than the size of the recess opening. Specific examples of such cases include application of the adhesive sheet, for example, to a hollow area surrounded by solder resist, a wiring layer, or the like on a wiring substrate. In the case of such an application, when the total of the thickness of the upper layer of the carrier film having a two-layer structure and the thickness of the adhesive layer is approximately equal to or greater than the depth of the recess, singulated adhesive can be easily applied to the recess bottom without deformation, lift of adhesive edge, or the like.

In the process for producing an adhesive sheet of the present invention, even when a brittle resin is used as an adhesive layer (b), rupture due to the stress upon peeling is less likely to occur. However, the stress on the adhesive layer (b) upon peeling increases as a peeling angle increases, and it increases as the stiffness of adhesive tape strengthens. Therefore, the adhesive tape, assuming that it is of the same material, is preferably as thin as possible to the extent that it is not difficult to convey, and the peeling angle is preferably as small as possible to the extent that peeling can be carried out.

Thus, the peeling angle between adhesive tape and an adhesive sheet during peeling preferably satisfies the relation shown below. In other words, as shown in FIG. 6, when a bending angle of the adhesive tape is taken as θ₁, and a bending angle of a carrier film (a) as θ₂, θ₁ and θ₂ preferably satisfy both of the following relations. θ₁ is defined as an angle between the extension of the adhesive tape in the pulling direction and the extension of the adhesive sheet before peeling, and θ₂ as an angle between the extension of the carrier film (a) in the pulling direction and the extension of the adhesive sheet before peeling.

|θ₁|<|θ₂| (I)

|θ₁|+|θ₂|<60° (II)

The stress during peeling of the adhesive layer (b) from the carrier film (a) is influenced more by θ₁ than by θ₂. Therefore, under conditions where (|θ₁|+|θ₂|) is fixed, stress on the adhesive layer (b) can be kept low when |θ₁| is smaller than |θ₂|. In addition, when (|θ₁|+θ₂|) is smaller than 60°, stress on the adhesive layer (b) upon peeling will not be too great, and chipping, rupture, and the like can be prevented. Chipping and rupture of the adhesive layer (b) can cause dust, and therefore it is preferable to prevent chipping and rupture not only of the adhesive layer (b) at desired parts but also of the adhesive layer (b) at unwanted parts.

The temperature during peeling is preferably 35° C. or higher because the adhesive layer (b) becomes soft and chipping and rupture can be prevented. The temperature during peeling is preferably 70° C. or lower because the adhesive layer (b) will not become too soft and the shape and thickness of singulated parts can be maintained.

The process for producing a wiring substrate having a singulated adhesive layer (b) according to the present invention comprises aligning the surface on the side of the adhesive layer (b) of an adhesive sheet obtained by the above production process with the surface on the side of wiring of a wiring substrate, forming a laminate comprising the adhesive sheet and the wiring substrate by vacuum lamination or vacuum press, and then removing an carrier film (a) of the adhesive sheet.

The adhesive sheet obtained after the step D having a singulated adhesive layer (b) on a carrier film (a) can be used by aligning the surface on the side of the adhesive layer (b) with the surface on the side of wiring of a wiring substrate and forming a laminate comprising the adhesive sheet and the wiring substrate by vacuum lamination or vacuum press. The vacuum press and vacuum lamination can be suitably used because air bubbles are less likely to be entrained between the wiring substrate and the adhesive layer (b).

The alignment of the surface on the side of the adhesive layer (b) of the adhesive sheet having a singulated adhesive layer (b) with the surface on the side of wiring of a wiring substrate may be performed by any method, for example, by recognizing a particular shape for position recognition formed on both sides using a camera. Alternatively, the alignment may be performed by providing through holes on both the adhesive sheet and the wiring substrate at a specific position where they should overlap each other, and inserting a pin such that the pin penetrates the through holes. The through holes may be formed by full-cutting only this part in the half-cutting process or may be formed by a different process.

In the vacuum press or vacuum lamination, a plurality of singulated adhesive layers (b) may be laminated on a wiring substrate collectively or piece by piece. When the wiring substrate is warped or bumpy, a plurality of singulated adhesive layers (b) may be pressed or laminated separately using a plurality of heads.

On the adhesive sheet, a singulated adhesive layer for temporary fixing not used for adhesion to a wiring substrate may be provided to perform temporary fixing immediately after alignment.

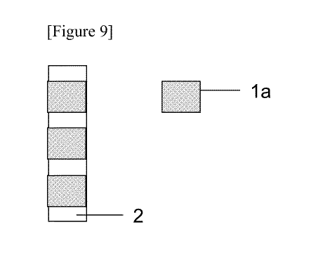

After the lamination, the carrier film (a) of the adhesive sheet is removed, whereby a wiring substrate having a singulated adhesive layer (b) at a specific position can be obtained. Transfer of the adhesive layer (b) to the wiring substrate may be carried out using the adhesive sheet as it is, or singulated pieces obtained by cutting the adhesive sheet may be used. For example, an adhesive sheet as shown in FIG. 8 in which an adhesive layer (b) is present on a carrier film (a) in succession is prepared, and the adhesive sheet may be cut to a desired length into a strip as shown in FIG. 9 and then transferred.

The method of manufacturing semiconductor equipment of the present invention is a method comprising mounting a semiconductor device on the wiring substrate described above.

The above-described wiring substrate having a singulated adhesive layer at a specific position can be used to manufacture semiconductor equipment by mounting a semiconductor device on a wiring substrate via an adhesive layer. For example, semiconductor equipment can be manufactured in such a manner that, using a flip chip bonder, a semiconductor chip on which bumps of Au or Cu are formed is connected to the wiring on a wiring substrate via an adhesive layer, and then the semiconductor chip and the wiring substrate are sealed with molding resin.

The equipment for producing an adhesive sheet of the present invention comprises a half-cutting apparatus, a cover film peeling apparatus, an adhesive tape applying apparatus, and an adhesive tape peeling apparatus in the order mentioned.

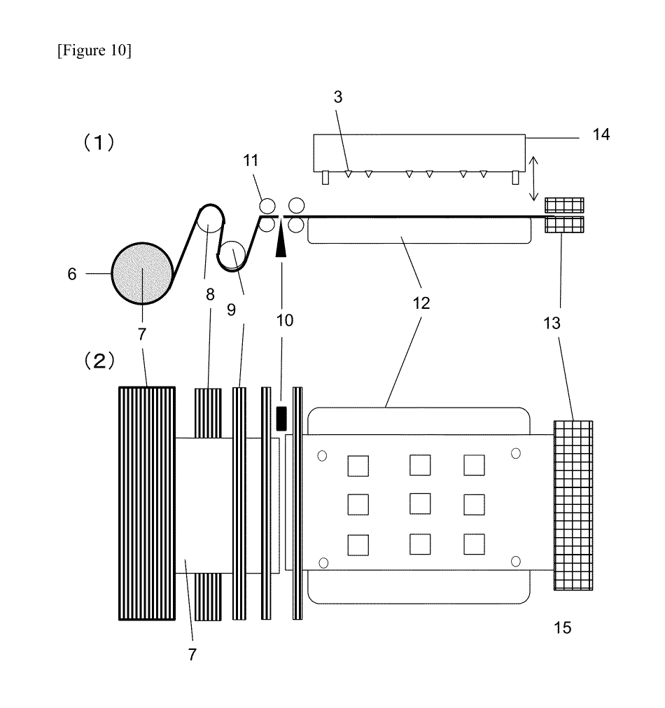

The half-cutting apparatus may be any apparatus as long as it is capable of cutting an adhesive film locally only at an adhesive layer (b) and a cover film (c) by means of local half-cutting, and a description will given with reference to FIG. 10, for example.

As shown in FIG. 10, using an adhesive film drawing clamp 13, a force to draw an adhesive film 6 holding its one end is applied to draw the adhesive film 6 from an adhesive film delivery roll 7. The adhesive film 6 is then sent to adhesive film tension rolls 11 via a conveying roll (1) 8 and a conveying roll (2) 9. As the slack in the adhesive film 6 is taken up with the adhesive film tension rolls 11, the adhesive film 6 is cut using an adhesive film cutting blade 10 to a size sufficient to be processed on the stage of an adsorptive fixation stage (1) 12.

The adhesive film 6 on the stage of the adsorptive fixation stage (1) 12 is then cut locally only at an adhesive layer (b) and a cover film (c) by means of local half-cutting using edges for half-cutting 3 provided on an upper plate 14. The upper plate 14 is movable up and down. The upper plate 14 is moved toward the adsorptive fixation stage (1) 12 to press the edges for half-cutting 3 against the adhesive film 6, whereby the cover film (c) and the adhesive layer (b) can be cut, and a carrier film (a) can be half-cut. When producing an adhesive sheet, such a mechanism can be used to separately cut adhesive parts to be left on the carrier film (a) for mounting a semiconductor.

The upper plate 14 is preferably provided with edges for forming through holes 15 as well as the edges for half-cutting 3. By virtue of this, the through holes 15 can be formed in the adhesive film 6 and can be used for the alignment as described above. To form the through holes 15, it is necessary to cut not only the cover film (c) and the adhesive layer (b) but also the carrier film (a), and, therefore, the edges for forming through holes 15 need to be longer than the edges for half-cutting 3 as required.

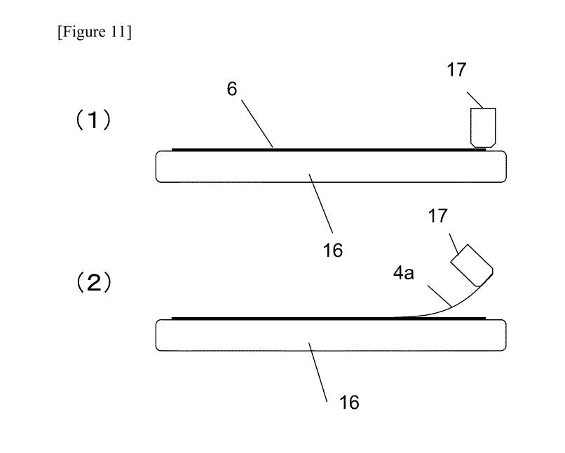

The cover film peeling apparatus may be any apparatus as long as it is capable of peeling only the cover film (c) at unwanted parts of the adhesive film after half-cutting, and a description will given with reference to FIG. 11, for example.

As shown in FIG. 11 (1), in the cover film peeling apparatus, the surface on the side of the carrier film (a) of the adhesive film 6 is adsorbed onto an adsorptive fixation stage (2) 16. A cover film (c) adsorptive (adhesive) arm 17 is then adsorbed at the end of the adhesive film 6.

As shown in FIG. 11 (2), the cover film (c) adsorptive (adhesive) arm 17 is moved in the direction away from the adsorptive fixation stage (2) to thereby peel the cover film (c). Thus, the cover film (c) on the adhesive film 6 after half-cutting can be peeled, but the cover film (c) at the uncut part is not peeled due to half-cutting.

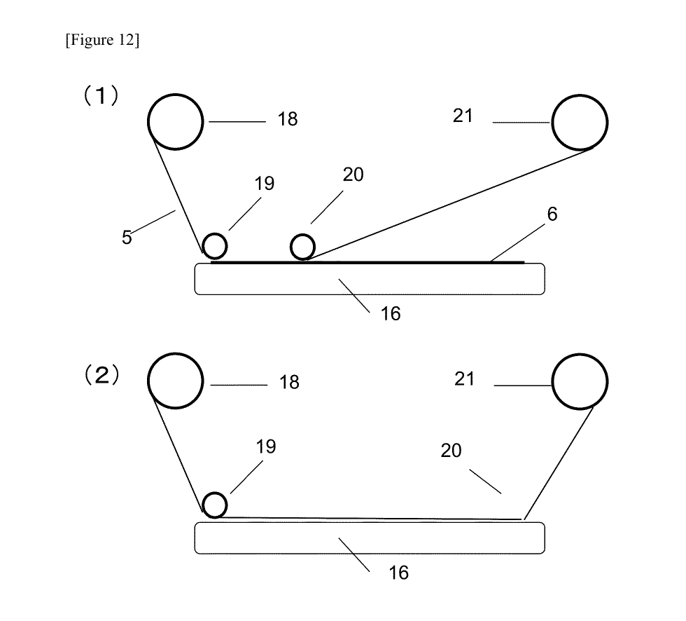

The adhesive tape applying apparatus may be any apparatus as long as it is capable of applying adhesive tape on the side of the cover film (c) of the adhesive film, and a description will given with reference to FIG. 12, for example.

An adhesive tape 5 supplied from an adhesive tape supply roll 18 is pressed via a adhesive tape end press roll 19 onto the adhesive film 6 from which the cover film (c) at unwanted parts has been peeled using the cover film peeling apparatus described above. Here, an adhesive tape laminating roll 20 is movable; it presses the adhesive tape 5 at a position adjacent to the adhesive tape end press roll 19 onto the adhesive film 6 adsorbed on the adsorptive fixation stage (2) 16, moves rightward from the position (FIG. 12 (1)), and finally moves to the right end of the adhesive film 6 (FIG. 12 (2)). Thus, the adhesive tape 5 can be laminated on the adhesive film 6.

The adhesive tape peeling apparatus may be any apparatus as long as it is capable of peeling the adhesive layer (b) at unwanted parts and the cover film (c) at desired parts of the adhesive film together with the adhesive tape, and a description will given with reference to FIG. 12, for example.

After the adhesive tape 5 is laminated on the adhesive film 6 using the adhesive tape applying apparatus described above, the adsorptive fixation stage (2) 16 is detached from the adhesive film 6, and the adhesive tape supply roll 18 and the adhesive tape end press roll 19 are also detached from the adhesive tape 5.

In FIG. 12, an end fixing roll for peeling (1) 22, an end fixing roll for peeling (2) 23, a moving roll for peeling (1) 24, a moving roll for peeling (2) 25, a moving roll for peeling (3) 26, a moving roll for peeling (4) 27, and a peeling clamp 28 are provided.

The peeling clamp 28 has a mechanism for moving downward while holding the end of the adhesive film 6. The moving roll for peeling (1) 24, the moving roll for peeling (2) 25, the moving roll for peeling (3) 26, and the moving roll for peeling (4) 27 are provided so as to adjust the size of θ₁ and θ₂ shown in FIG. 12, which determines the relative position with respect to an adhesive tape take-up roll 21. These moving rolls for peeling may comprise a heating mechanism.

When producing an adhesive sheet, the relative position of these moving rolls for peeling with respect to the adhesive tape take-up roll 21 is moved leftward in FIG. 12 while controlling θ₁ and θ₂. While doing this, the adhesive tape take-up roll 21 is rotated to take up the adhesive tape 5, thereby removing the adhesive layer (b) at unwanted parts and the cover film (c) at desired parts on the adhesive film 6. To prevent chipping and rupture of the adhesive layer (b), all or some of the moving rolls for peeling may be heated to heat the adhesive film 6.

The adhesive sheet of the present invention can be obtained as described above.

### EXAMPLES

The process for producing an adhesive sheet having a singulated adhesive layer (b) on a carrier film (a) according to the present invention will now be described in more detail, but the present invention is not limited thereto.

Evaluation methods will be described below.

### (1) Measurement of Infrared Absorption Spectrum of Polyimide Resin

Measurements were made by the KBr method using FT-IR720 available from HORIBA, Ltd.

### (2) Measurement of Weight Average Molecular Weight of Polyimide Resin

Gel Permeation Chromatography (Waters 2690 available from Nihon Waters K.K.) was used to determine the weight average molecular weight in terms of polystyrene. The columns used were TOSOH TXK-GEL α-2500 and α-4000 available from TOSOH Corporation, and the moving bed used was N-methyl-2-pyrrolidone (hereinafter referred to as NMP).

### (3) Measurement of Melt Viscosity

A sample obtained was cut into a circle 15 mm in diameter, and its melt viscosity was measured using a rheometer (AR-G2) manufactured by TA Instruments at a strain of 1%, a frequency of 1 Hz, and a temperature rise rate of 5° C./min.

### (4) Measurement of Peel Force at 25° C. Between Adhesive Layer (b) and Carrier Film (a) and Between Adhesive Layer (b) and Cover Film (c)

An adhesive film was cut to a width of 20 mm, and the surface on the side of a carrier film (a) of the adhesive film was bonded to a substrate made of SUS with double-sided tape. In a measuring chamber in which the temperature was controlled at 25° C., the sample obtained was set on a tensile tester (Tensilon manufactured by Orientec Co., Ltd.) with a cover film (c) being peeled in the 90° direction, and the cover film (c) was pulled in the 90° direction at a peeling rate of 50 mm/min to determine the force required for peeling, which was used as a peel force at 25° C. between a adhesive layer (b) and the cover film (c).

The cover film (c) was peeled off the adhesive film, and the side of the adhesive layer (b) was bonded to a substrate made of SUS with double-sided tape. In a measuring chamber in which the temperature was controlled at 25° C., the sample obtained was set on a tensile tester (Tensilon manufactured by Orientec Co., Ltd.) with the carrier film (a) being peeled in the 90° direction, and the carrier film (a) was pulled in the 90° direction at a peeling rate of 50 mm/min to determine the force required for peeling, which was used as a peel force at 25° C. between the adhesive layer (b) and the carrier film (a).

### <Polyimide Resin>

### Synthesis of Polyimide Resin 1

Under a stream of dry nitrogen, 24.54 g (0.067 mol) of 2,2-bis(3-amino-4-hydroxyphenyl)hexafluoropropane (hereinafter referred to as BAHF), 4.97 g (0.02 mol) of 1,3-bis(3-aminopropyl)tetramethyldisiloxane (hereinafter referred to as SiDA), and 1.86 g (0.02 mol) of aniline that serves as an end-capping agent were dissolved in 80 g of NMP. To the resulting mixture, 31.02 g (0.1 mol) of bis(3,4-dicarboxyphenyl) ether dianhydride (hereinafter referred to as ODPA) was added together with 20 g of NMP, and the resulting mixture was allowed to react at 20° C. for 1 hour and then stirred at 50° C. for 4 hours. Thereafter, 15 g of xylene was added thereto, and the resulting mixture was stirred at 180° C. for 5 hours while azeotroping water with xylene. After stirring, the resulting solution was poured into 3 L of water to obtain a white precipitated polymer. The precipitate was recovered by filtration, washed three times with water, and then dried at 80° C. for 20 hours with a vacuum dryer. The infrared absorption spectrum of the polymer solid obtained was measured to detect absorption peaks of an imide structure derived from polyimide at around 1,780 cm⁻¹ and around 1,377 cm⁻¹. A polyimide resin 1 having a weight average molecular weight of about 25,000 was obtained.

### Synthesis of Polyimide Resin 2

Under a stream of dry nitrogen, 52 g (0.1 mol) of 2,2-bis(4-(3,4-dicarboxyphenoxyl)phenyl)propane dianhydride (hereinafter referred to as BPADA), 10.93 g (0.044 mol) of SiDA, and 15.91 g (0.055 mol) of 1,3-bis(3-aminophenoxy)benzene were dissolved in 200 g of NMP. Thereafter, the resulting mixture was stirred at 70° C. for 1 hour, and then stirred at 190° C. for 3 hours. After stirring, the resulting solution was poured into 3 L of water to obtain a white precipitated polymer. The precipitate was recovered by filtration, washed three times with water, and then dried at 80° C. for 100 hours with a vacuum dryer. The infrared absorption spectrum of the polymer solid obtained was measured to detect absorption peaks of an imide structure derived from polyimide at around 1,780 cm⁻¹ and around 1,377 cm⁻¹. A polyimide resin 2 having a weight average molecular weight of about 30,000 was obtained.

### <Phenoxy Resin>

YP-50 (weight average molecular weight: 60,000 to 80,000, available from Nippon Steel Chemical Co., Ltd.)

### <Solid Epoxy Compound>

157S70 (trade name, available from Mitsubishi Chemical Corporation)

### <Curing Accelerator>

Microcapsulated curing accelerator NOVACURE HX-3941HP (trade name, available from Asahi Kasei E-materials Corporation)

### <Filler>

SO-E2 (trade name, available from Admatechs Co., Ltd., spherical silica particles, average particle size: 0.5 μm)

### Preparation and Evaluation of Adhesive Film 1

Twenty-five grams of the polyimide resin 1 obtained by synthesis, 30 g of a solid epoxy compound 157S70, 45 g of a curing accelerator NOVACURE HX-3941HP, 100 g of a filler SO-E2, and 80 g of solvent methyl isobutyl ketone were mixed and stirred to disperse the filler and the curing accelerator particles. The adhesive varnish obtained was applied to the surface to be treated of a polyethylene terephthalate film (treated with AL-5, available from Lintec Corporation) with a thickness of 38 μm, which is a base film, using a comma coater (coating machine), and dried at 90° C. for 10 minutes to form an adhesive layer (b) with a dry thickness of 32 μm. A protective film (treated with SK-1, available from Lintec Corporation) with a thickness of 25 μm was laminated on the adhesive layer (b) at 70° C. to obtain an adhesive film 1. In the adhesive film 1, the base film serves as the carrier film (a), and the protective film serves as the cover film (c).

The cover film (c) was then peeled from the adhesive film 1, and the resulting samples were laminated at 60° C. with the adhesive layer (b) facing each other. Peeling of one of the carrier films (a) of the laminated sample and further lamination was repeated until the thickness of the adhesive layer (b) reached 800 μm. Thereafter, the carrier film (a) was peeled to obtain a sample, the melt viscosity of which was measured with a rheometer to be 700 Pa·s at 100° C. Further, the peel force between the carrier film (a) and the adhesive layer (b) of the adhesive film 1 was measured to be 10 N/m, and the peel force between the cover film (c) and the adhesive layer (b) of the adhesive film 1 was 5 N/m.

### Preparation and Evaluation of Adhesive Film 2

An adhesive film 2 was prepared in the same manner as in the preparation of the adhesive film 1 above except using a polyethylene terephthalate film (38E-NSH, available from Fujimori Sangyo Co., Ltd.) of 38 μm as a base film. In the adhesive film 2, the base film serves as the carrier film (a), and the protective film serves as the cover film (c). The adhesive film 2 was evaluated similarly to the adhesive film 1 above to have a melt viscosity at 100° C. of 700 Pa·s, a peel force between the carrier film (a) and the adhesive layer (b) of 30 N/m, and a peel force between the cover film (c) and the adhesive layer (b) of 5 N/m. The physical properties of the adhesive film 2 were equivalent to those of the adhesive film 1 except that the adhesion was different because of the difference in release treatment of the carrier film (a).

### Preparation and Evaluation of Adhesive Film 3

Twenty-five grams of the polyimide resin 2 obtained by synthesis, 30 g of a solid epoxy compound 157570, 45 g of a curing accelerator NOVACURE HX-3941HP, 100 g of a filler SO-E2, and 80 g of solvent methyl isobutyl ketone were mixed and stirred to disperse the filler and the curing accelerator particles. The adhesive varnish obtained was applied to the surface to be treated of a polyethylene terephthalate film (treated with AL-5, available from Lintec Corporation) with a thickness of 38 μm, which is a base film, using a comma coater (coating machine), and dried at 90° C. for 10 minutes to form an adhesive layer (b) with a dry thickness of 32 μm. A protective film (treated with SK-1, available from Lintec Corporation) with a thickness of 25 μm was laminated on the adhesive layer (b) at 70° C. to obtain an adhesive film 3. In the adhesive film 3, the base film serves as the carrier film (a), and the protective film serves as the cover film (c).

The cover film (c) was then peeled from the adhesive film 3, and the resulting samples were laminated at 80° C. with the adhesive layer (b) facing each other. Peeling of one of the carrier films (a) of the laminated sample and further lamination was repeated until the thickness of the adhesive layer (b) reached 800 μm. Thereafter, the carrier film (a) was peeled to obtain a sample, the melt viscosity of which was measured with a rheometer to be 2,500 Pa·s at 100° C. Further, the peel force between the carrier film (a) and the adhesive layer (b) of the adhesive film 3 was measured to be 5 N/m, and the peel force between the cover film (c) and the adhesive layer (b) of the adhesive film 3 was 2 N/m.

### Preparation and Evaluation of Adhesive Film 4

Twenty-five grams of a phenoxy resin YP-50, 30 g of a solid epoxy compound 157S70, 45 g of a curing accelerator NOVACURE HX-3941HP, 100 g of a filler SO-E2, and 80 g of solvent toluene were mixed and stirred to disperse the filler and the curing accelerator particles. The adhesive varnish obtained was applied to the surface to be treated of a polyethylene terephthalate film (38E-NSH, available from Fujimori Sangyo Co., Ltd.) with a thickness of 38 μm, which is a base film, using a comma coater (coating machine), and dried at 90° C. for 10 minutes to form an adhesive layer (b) with a dry thickness of 32 μm. A protective film (treated with AL-5, available from Lintec Corporation) with a thickness of 25 μm was laminated on the adhesive layer (b) at 80° C. to obtain an adhesive film 4. In the adhesive film 4, the base film serves as the carrier film (a), and the protective film serves as the cover film (c).

The cover film (c) was then peeled from the adhesive film 4, and the resulting samples were laminated at 80° C. with the adhesive layer (b) facing each other. Peeling of one of the carrier films (a) of the laminated sample and further lamination was repeated until the thickness of the adhesive layer (b) reached 800 μm. Thereafter, the carrier film (a) was peeled to obtain a sample, the melt viscosity of which was measured with a rheometer to be 7,000 Pa·s at 100° C. Further, the peel force between the carrier film (a) and the adhesive layer (b) of the adhesive film 4 was measured to be 10 N/m, and the peel force between the cover film (c) and the adhesive layer (b) of the adhesive film 4 was 2 N/m.

### <Adhesive Tape>

31B (available from NITTO DENKO CORPORATION, 53 μm thick) No. 603 #25 (available from Teraoka Seisakusho Co., Ltd., total thickness: 34 μm, two-layer structure of a carrier film (polyester, thickness: 25 μm) and an adhesive layer (thickness: 9 μm))
No. 631U #12 (available from Teraoka Seisakusho Co., Ltd., total thickness: 25 μm, two-layer structure of a carrier film (polyester, thickness: 12 μm) and an adhesive layer (thickness: 13 μm))
UHP0810AT available from DENKI KAGAKU KOGYO KABUSHIKI KAISHA, total thickness: 90 μm, two-layer structure of a carrier film (polyolefin, 80 μm) and an adhesive layer (thickness: 10 m))

### Example 1

The adhesive film 1 was placed on a pinnacle die (available from TSUKATANI HAMONO MFG. CO., LTD.) provided with sixteen 8.5-mm square edges such that the side of the cover film (c) was in contact with the pinnacle die, and the cover film (c) and the adhesive layer (b) were half-cut with a rotary die cutter (available from TSUKATANI HAMONO MFG. CO., LTD.). After the half-cutting, one end of the cover film (c) was pulled to remove unwanted parts of the cover film (c). After removing the unwanted parts, the adhesive film 1 was fixed on a bench with the cover film (c) up, and 31B tape was applied to the side of the cover film (c) of the adhesive film using a roller to obtain a sheet to which the 31B tape was applied. The adhesive tape was then pulled, while holding a peeling point with a roller, in the 30° direction with respect to the bench to remove the adhesive tape (θ₁=30°, θ₂=0°). After the peeling, an adhesive sheet in which sixteen 8.5-mm square adhesives were formed on the carrier film (a) was obtained. The adhesive sheet obtained was inspected for chipping and the like at the adhesive part, and the number of adhesive sheets without breakage or the like (the number of successes) was counted. The results are shown in Table 1.

### Example 2

A sheet to which the 31B tape was applied was obtained in the same manner as in Example 1, and then the sample was fixed on a bench with the carrier film (a) up. The base film was pulled in the 30° direction, while holding a peeling point with a roller, to remove the adhesive tape (θ₁=0°, θ₂=30°). After the peeling, an adhesive sheet in which sixteen 8.5-mm square adhesives were formed on the carrier film (a) was obtained. The adhesive sheet obtained was inspected for chipping and the like at the adhesive part, and the number of adhesive sheets without breakage or the like (the number of successes) was counted. The results are shown in Table 1.

### Examples 3 to 5

An adhesive sheet was obtained in the same manner as in Example 1 except that θ₁ was changed as shown in Table 1. The adhesive sheet obtained was inspected for chipping and the like at the adhesive part, and the number of adhesive sheets without breakage or the like (the number of successes) was counted. The results are shown in Table 1.

### Examples 6 to 8

An adhesive sheet was obtained in the same manner as in Example 2 except that θ₂ was changed as shown in Table 2. The adhesive sheet obtained was inspected for chipping and the like at the adhesive part, and the number of adhesive sheets without breakage or the like (the number of successes) was counted. The results are shown in Table 2.

### Example 9

An adhesive sheet was obtained in the same manner as in Example 1 except that No. 603 #25 was used as adhesive tape in place of 31B. When No. 603 #25 was applied to the side of the cover film (c) of the adhesive film, the surface on the side of an adhesive layer was aligned with the surface on the side of the cover film (c). The adhesive sheet obtained was inspected for chipping and the like at the adhesive part, and the number of adhesive sheets without breakage or the like (the number of successes) was counted. The results are shown in Table 2.

### Example 10

An adhesive sheet was obtained in the same manner as in Example 2 except that No. 603 #25 was used as adhesive tape in place of 31B. When No. 603 #25 was applied to the side of the cover film (c) of the adhesive film, the surface on the side of an adhesive layer was aligned with the surface on the side of the cover film (c). The adhesive sheet obtained was inspected for chipping and the like at the adhesive part, and the number of adhesive sheets without breakage or the like (the number of successes) was counted. The results are shown in Table 2.

### Example 11

An adhesive sheet was obtained in the same manner as in Example 1 except that No. 631U #12 was used as adhesive tape in place of 31B. When No. 631U #12 was applied to the side of the cover film (c) of the adhesive film, the surface on the side of an adhesive layer was aligned with the surface on the side of the cover film (c). The adhesive sheet obtained was inspected for chipping and the like at the adhesive part, and the number of adhesive sheets without breakage or the like (the number of successes) was counted. The results are shown in Table 3.

### Example 12

An adhesive sheet was obtained in the same manner as in Example 2 except that No. 631U #12 was used as adhesive tape in place of 31B. When No. 631U #12 was applied to the side of the cover film (c) of the adhesive film, the surface on the side of an adhesive layer was aligned with the surface on the side of the cover film (c). The adhesive sheet obtained was inspected for chipping and the like at the adhesive part, and the number of adhesive sheets without breakage or the like (the number of successes) was counted. The results are shown in Table 3.

### Examples 13, 15

An adhesive sheet was obtained in the same manner as in Example 11 except that θ₁ was changed as shown in Table 3. The adhesive sheet obtained was inspected for chipping and the like at the adhesive part, and the number of adhesive sheets without breakage or the like (the number of successes) was counted. The results are shown in Table 3.

### Examples 14, 16

An adhesive sheet was obtained in the same manner as in Example 12 except that θ₂ was changed as shown in Table 3. The adhesive sheet obtained was inspected for chipping and the like at the adhesive part, and the number of adhesive sheets without breakage or the like (the number of successes) was counted. The results are shown in Table 3.

### Example 17

The adhesive film 2 was placed on a pinnacle die (available from TSUKATANI HAMONO MFG. CO., LTD.) provided with sixteen 8.5-mm square edges such that the side of the cover film (c) was in contact with the pinnacle die, and the cover film (c) and the adhesive layer (b) were half-cut with a rotary die cutter (available from TSUKATANI HAMONO MFG. CO., LTD.). After the half-cutting, one end of the cover film (c) was pulled to remove unwanted parts of the cover film (c). After removing the unwanted parts, the adhesive film 1 was fixed on a bench with the cover film (c) up, and the surface on the side of an adhesive layer of No. 631U #12 was applied to the side of the cover film (c) of the adhesive film 2 using a roller to obtain a sheet to which No. 631U #12 was applied. The adhesive tape was then pulled, while holding a peeling point with a roller, in the 30° direction with respect to the bench to remove the adhesive tape (θ₁=30°, θ₂=0°). After the peeling, an adhesive sheet in which sixteen 8.5-mm square adhesives were formed on the carrier film (a) was obtained. The adhesive sheet obtained was inspected for chipping and the like at the adhesive part, and the number of adhesive sheets without breakage or the like (the number of successes) was counted. The results are shown in Table 4.

### Examples 18, 19

An adhesive sheet was obtained in the same manner as in Example 17 except that the adhesive film was changed as shown in Table 4. The adhesive sheet obtained was inspected for chipping and the like at the adhesive part, and the number of adhesive sheets without breakage or the like (the number of successes) was counted. The results are shown in Table 4.

### Example 20

An adhesive sheet was obtained in the same manner as in Example 1 except that UHP0810AT was used as adhesive tape in place of 31B. When UHP0810AT was applied to the side of the cover film (c) of the adhesive film, the surface on the side of an adhesive layer was aligned with the surface on the side of the cover film (c). The adhesive sheet obtained was inspected for chipping and the like at the adhesive part, and the number of adhesive sheets without breakage or the like (the number of successes) was counted. The results are shown in Table 5.

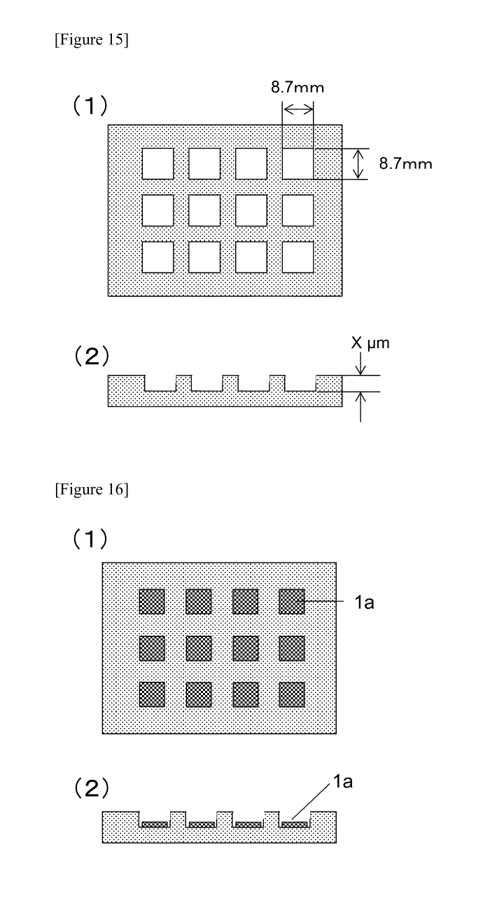

Experiments were performed in which singulated parts of the adhesive sheet obtained were bonded to the bottom of 8.7-mm square open recesses of a substrate shown in FIG. 15 (1) and (2). Positioning was performed in such a manner that the center of the singulated parts of the adhesive sheet was aligned with the center of the open recesses so that four sides of the singulated parts of the adhesive sheet were parallel to four sides of the bottom of the recesses, and then bonding was performed using a vacuum laminator (CVP300T manufactured by Nichigo-Morton Co., Ltd.). The experiments were performed at a heating temperature of 80° C. and an applied pressure of 0.5 MPa. When the adhesive could be applied to the recess bottom without voids or lift, it was considered a success, and when peeling or lift occurred, it was considered a failure. The experiments were performed using substrates having a recess depth (X) of 200 μm, 160 μm, 110 μm, 80 μm, 50 μm, and 30 μm, and the results are shown in Table 6.

### Example 21

An adhesive sheet was obtained in the same manner as in Example 2 except that UHP0810AT was used as adhesive tape in place of 31B. When UHP0810AT was applied to the side of the cover film (c) of the adhesive film, the surface on the side of an adhesive layer was aligned with the surface on the side of the cover film (c). The adhesive sheet obtained was inspected for chipping and the like at the adhesive part, and the number of adhesive sheets without breakage or the like (the number of successes) was counted. The results are shown in Table 5.

### Examples 22, 24

An adhesive sheet was obtained in the same manner as in Example 20 except that θ₁ was changed as shown in Table 5. The adhesive sheet obtained was inspected for chipping and the like at the adhesive part, and the number of adhesive sheets without breakage or the like (the number of successes) was counted. The results are shown in Table 5.

### Examples 23, 25

An adhesive sheet was obtained in the same manner as in Example 21 except that θ₂ was changed as shown in Table 5. The adhesive sheet obtained was inspected for chipping and the like at the adhesive part, and the number of adhesive sheets without breakage or the like (the number of successes) was counted. The results are shown in Table 5.

### Example 26

The adhesive film 2 was placed on a pinnacle die (available from TSUKATANI HAMONO MFG. CO., LTD.) provided with sixteen 8.5-mm square edges such that the side of the cover film (c) was in contact with the pinnacle die, and the cover film (c) and the adhesive layer (b) were half-cut with a rotary die cutter (available from TSUKATANI HAMONO MFG. CO., LTD.). After the half-cutting, one end of the cover film (c) was pulled to remove unwanted parts of the cover film (c). After removing the unwanted parts, the adhesive film 2 was fixed on a bench with the cover film (c) up, and the surface on the side of an adhesive layer of UHP0810AT was applied to the side of the cover film (c) of the adhesive film 2 using a roller to obtain a sheet to which UHP0810AT was applied. The adhesive tape was then pulled, while holding a peeling point with a roller, in the 30° direction with respect to the bench to remove the adhesive tape (θ₁=30°, θ₂=0°). After the peeling, an adhesive sheet in which sixteen 8.5-mm square adhesives were formed on the carrier film (a) was obtained. The adhesive sheet obtained was inspected for chipping and the like at the adhesive part, and the number of adhesive sheets without breakage or the like (the number of successes) was counted. The results are shown in Table 7.

### Examples 27, 28

An adhesive sheet was obtained in the same manner as in Example 26 except that the adhesive film was changed as shown in Table 7. The adhesive sheet obtained was inspected for chipping and the like at the adhesive part, and the number of adhesive sheets without breakage or the like (the number of successes) was counted. The results are shown in Table 7.

### Example 29

The adhesive film 1 was placed on a pinnacle die (available from TSUKATANI HAMONO MFG. CO., LTD.) provided with sixteen 8.5-mm square edges such that the side of the cover film (c) was in contact with the pinnacle die, and the cover film (c) and the adhesive layer (b) were half-cut with a rotary die cutter (available from TSUKATANI HAMONO MFG. CO., LTD.). After the half-cutting, one end of the cover film (c) was pulled to remove unwanted parts of the cover film (c). After removing the unwanted parts, the adhesive film 1 was fixed with the cover film (c) up on a hot plate controlled such that the adhesive film 1 had a surface temperature of 30° C., and 31B tape was applied to the side of the cover film (c) of the adhesive film using a roller to obtain a sheet to which the 31B tape was applied. The temperature control of the hot plate was performed by measuring the surface temperature of the adhesive film 1 with a thermocouple. The base film was then pulled in the 30° direction, while holding a peeling point with a roller, to remove the adhesive tape (θ₁=0°, θ₂=30°). After the peeling, an adhesive sheet in which sixteen 8.5-mm square adhesives were formed on the carrier film (a) was obtained. The adhesive sheet obtained was inspected for chipping and the like at the adhesive part, and the number of adhesive sheets without breakage or the like (the number of successes) was counted. The results are shown in Table 8.

### Examples 30 to 33

An adhesive sheet was obtained in the same manner as in Example 29 except that the surface temperature of the adhesive film 1 controlled by the hot plate was changed as shown in Table 8. In Example 33, chipping or breakage was not observed, but deformation of the adhesive layer (b) was observed.

### Example 34

An adhesive sheet was obtained in the same manner as in Example 20 except that an adhesive film comprising a two-layer carrier film, which was obtained by laminating an adhesive-backed PET film 631 S2#50 (available from Teraoka Seisakusho Co., Ltd., PET film thickness: 50 μm, total thickness including adhesive layer: 85 μm, peel force relative to PET film: 6.7 N/m) on the surface opposite to the adhesive layer-forming surface of the carrier film of the adhesive film 1, was substituted for the adhesive film 1; and half-cutting was performed halfway through 630#75 in the thickness direction. The adhesive sheet obtained was inspected for chipping and the like at the adhesive part, and the number of adhesive sheets without breakage or the like (the number of successes) was counted. The number of successes was 16 out of 16. The structure of singulated parts of the adhesive sheet obtained was the same as that shown in FIG. 14.

Experiments were performed in which singulated parts of the adhesive sheet obtained were bonded to the bottom of 8.7-mm square open recesses of a substrate shown in FIG. 15 (1) and (2). Positioning was performed in such a manner that the center of the singulated parts of the adhesive sheet was aligned with the center of the open recesses so that four sides of the singulated parts of the adhesive sheet were parallel to four sides of the bottom of the recesses, and then bonding was performed using a vacuum laminator (CVP300T manufactured by Nichigo-Morton Co., Ltd.). The experiments were performed at a heating temperature of 80° C. and an applied pressure of 0.5 MPa. When the adhesive could be applied to the recess bottom without voids or lift, it was considered a success, and when peeling or lift occurred, it was considered a failure. The experiments were performed using substrates having a recess depth (X) of 200 μm, 160 μm, 110 μm, 80 μm, 50 μm, and 30 μm, and the results are shown in Table 9.

### Comparative Example

The adhesive film 1 was placed on a pinnacle die (available from TSUKATANI HAMONO MFG. CO., LTD.) provided with sixteen 8.5-mm square edges such that the side of the cover film (c) was in contact with the pinnacle die, and the cover film (c) and the adhesive layer (b) were half-cut with a rotary die cutter (available from TSUKATANI HAMONO MFG. CO., LTD.). After the half-cutting, one end of the cover film (c) was pulled to remove unwanted parts of the cover film (c). Removal of unwanted parts of the adhesive layer (b) was then attempted without applying adhesive tape. However, the adhesive layer (b) could not withstand the tension and ruptured, and an adhesive sheet in which a singulated adhesive was formed on the carrier film (a) could not be obtained.

TABLE 1

| | | Example 1 | Example 2 | Example 3 | Example 4 | Example 5 |
|---|---|---|---|---|---|---|
| Adhesive tape | | 31B | 31B | 31B | 31B | 31B |
| Peel angle | θ₁ | 30° | 0° | 45° | 60° | 90° |
| | θ₂ | 0° | 30° | 0° | 0° | 0° |

| | | | | | |
|---|---|---|---|---|---|
| Successful numbers | 10 pieces/16 pieces | 12 pieces/16 pieces | 9 pieces/16 pieces | 8 pieces/16 pieces | 6 pieces/16 pieces |

TABLE 2

| | | Example 6 | Example 7 | Example 8 | Example 9 | Example 10 |
|---|---|---|---|---|---|---|
| Adhesive tape | | 31B | 31B | 31B | No. 603 #25 | No. 603 #25 |
| Peel angle | θ₁ | 0° | 0° | 0° | 30° | 0° |
| | θ₂ | 45° | 60° | 90° | 0° | 30° |

| | | | | | |
|---|---|---|---|---|---|
| Successful numbers | 11 pieces/16 pieces | 11 pieces/16 pieces | 8 pieces/16 pieces | 13 pieces/16 pieces | 16 pieces/16 pieces |

TABLE 3

| | | Example 11 | Example 12 | Example 13 | Example 14 | Example 15 | Example 16 |
|---|---|---|---|---|---|---|---|
| Adhesive tape | | No. 631U #12 | No. 631U #12 | No. 631U #12 | No. 631U #12 | No. 631U #12 | No. 631U #12 |
| Peel angle | θ₁ | 30° | 0° | 60° | 0° | 90° | 0° |
| | θ₂ | 0° | 30° | 0° | 60° | 0° | 90° |

| | | | | | | |
|---|---|---|---|---|---|---|
| Successful numbers | 16 pieces/16 pieces | 16 pieces/16 pieces | 14 pieces/16 pieces | 16 pieces/16 pieces | 10 pieces/16 pieces | 12 pieces/16 pieces |

TABLE 4

| | | Example 17 | Example 18 | Example 19 |
|---|---|---|---|---|
| Adhesive film | | Adhesive film 2 | Adhesive film 3 | Adhesive film 4 |
| Adhesive tape | | No. 631U #12 | No. 631U #12 | No. 631U #12 |
| Peel | θ₁ | 30° | 30° | 30° |
| angle | θ₂ | 0° | 0° | 0° |

| | | | |
|---|---|---|---|
| Successful | 10 pieces/ | 16 pieces/ | 16 pieces/ |
| numbers | 16 pieces | 16 pieces | 16 pieces |

TABLE 5

| | | Example 20 | Example 21 | Example 22 | Example 23 | Example 24 | Example 25 |
|---|---|---|---|---|---|---|---|
| Adhesive tape | | UHP0810AT | UHP0810AT | UHP0810AT | UHP0810AT | UHP0810AT | UHP0810AT |
| Peel angle | θ₁ | 30° | 0° | 60° | 0° | 90° | 0° |
| | θ₂ | 0° | 30° | 0° | 60° | 0° | 90° |

| | | | | | | |
|---|---|---|---|---|---|---|
| Successful numbers | 16 pieces/16 pieces | 16 pieces/16 pieces | 16 pieces/16 pieces | 16 pieces/16 pieces | 14 pieces/16 pieces | 15 pieces/16 pieces |

TABLE 6

| | X (μm) | | | | | |
|---|---|---|---|---|---|---|
| | 200 | 160 | 110 | 80 | 50 | 30 |
| Successful | 0 piece/16 pieces | 0 pieces/16 pieces | 0 pieces/16 pieces | 10 pieces/16 pieces | 15 pieces/16 pieces | 16 pieces/16 pieces |
| numbers | | | | | | |

TABLE 7

| | | Example 26 | Example 27 | Example 28 |
|---|---|---|---|---|
| Adhesive film | | Adhesive film 2 | Adhesive film 3 | Adhesive film 4 |
| Adhesive tape | | UHP0810AT | UHP0810AT | UHP0810AT |
| Peel | θ₁ | 30° | 30° | 30° |
| angle | θ₂ | 0° | 0° | 0° |

| | | | |
|---|---|---|---|
| Successful | 14 pieces/ | 16 pieces/ | 16 pieces/ |
| numbers | 16 pieces | 16 pieces | 16 pieces |

TABLE 8

| | | Example 29 | Example 30 | Example 31 | Example 32 | Example 33 |
|---|---|---|---|---|---|---|
| Adhesive tape | | 31B | 31B | 31B | 31B | 31B |
| Temperature (° C.) | | 30 | 35 | 50 | 70 | 75 |
| Peel angle | θ₁ | 0° | 0° | 0° | 0° | 0° |
| | θ₂ | 30° | 30° | 30° | 30° | 30° |

| | | | | | |
|---|---|---|---|---|---|
| Successful numbers | 12 pieces/16 pieces | 14 pieces/16 pieces | 15 pieces/16 pieces | 15 pieces/16 pieces | 15 pieces/16 pieces |

TABLE 9

| | X (μm) | | | | | |
|---|---|---|---|---|---|---|
| | 200 | 160 | 110 | 80 | 50 | 30 |
| Successful | 2 pieces/16 pieces | 12/16 pieces | 16 pieces/16 pieces | 16 pieces/16 pieces | 16 pieces/16 pieces | 16 pieces/16 pieces |
| numbers | | | | | | |

### INDUSTRIAL APPLICABILITY

According to the present invention, an adhesive sheet comprising a singulated adhesive disposed at a specific position can be produced, and transferring the adhesive to a wiring substrate can expand its application, for example, to a wiring substrate for flip chip assembly of a semiconductor. The adhesive sheet of the present invention can be advantageously used for precise application of a highly fluid and brittle adhesive to a wiring substrate, for example, in a non-conductive film (NCF) for semiconductor assembly.

### DESCRIPTION OF SYMBOLS

1a: Singulated adhesive layer (b) (wanted part)
1b: Adhesive layer (b) at unwanted parts
2: Carrier film (a)
2a: Upper layer of two-layer carrier film
2b: Lower layer of two-layer carrier film
3: Edges for half-cutting
4a: Cover film (c) at unwanted parts
4b: Cover film (c) at wanted part
5: Adhesive tape
6: Adhesive film (cover film (c)/adhesive layer (b)/carrier film (a))
7: Adhesive film delivery roll
8: Conveying roll (1)
9: Conveying roll (2)
10: Adhesive film cutting blade
11: Adhesive film tension roll
12: Adsorptive fixation stage (1)
13: Adhesive film drawing clamp
14: Upper plate
15: Through holes
16: Adsorptive fixation stage (2)
17: Cover film (c) adsorptive (adhesive) arm
18: Adhesive tape supply roll
19: Adhesive tape end press roll
20: Adhesive tape laminating roll
21: Adhesive tape take-up roll
22: End fixing roll for peeling (1)
23: End fixing roll for peeling (2)
24: Moving roll for peeling (1)
25: Moving roll for peeling (2)
26: Moving roll for peeling (3)
27: Moving roll for peeling (4)
28: Peeling clamp

1. A process for producing an adhesive sheet having a singulated adhesive layer (b) on a carrier film (a), comprising the following steps in the order mentioned:
Step A: cutting an adhesive film having a carrier film (a), an adhesive layer (b), and a cover film (c) in the order mentioned locally only at the adhesive layer (b) and the cover film (c) by means of local half-cutting;
Step B: peeling only the cover film (c) at unwanted parts of the adhesive film;
Step C: applying adhesive tape to the side of the cover film (c) of the adhesive film; and
Step D: peeling the adhesive layer (b) at unwanted parts and the cover film (c) at desired parts of the adhesive film together with the adhesive tape.

2. The process for producing an adhesive sheet having a singulated adhesive layer according to claim 1, wherein the carrier film (a) has a two-layer structure that can be peeled at the lamination interface.

3. The process for producing an adhesive sheet having a singulated adhesive layer according to claim 1, wherein the adhesive tape has a carrier film (a′) and an adhesive layer (b′), the carrier film (a′) being made of a polyolefin.

4. The process for producing an adhesive sheet having a singulated adhesive layer according to claim 1, wherein the adhesive tape has a thickness of 10 to 40 μm.

5. The process for producing an adhesive sheet having a singulated adhesive layer according to claim 1, wherein in the peeling of the step D, a bending angle of the adhesive tape (θ1) and a bending angle of the carrier film (a) (θ2) satisfy the following expressions (I) and (II):

|θ1|<|θ2| (I)

|θ1|+|θ2|<60° (II).

6. A process for producing a wiring substrate, comprising:
aligning the surface on the side of the adhesive layer (b) of an adhesive sheet obtained by the production method according to claim 1 with the surface on the side of wiring of a wiring substrate, forming a laminate comprising the adhesive sheet and the wiring substrate by vacuum lamination or vacuum press, and then removing a carrier film (a) of the adhesive sheet.

7. A method of manufacturing semiconductor equipment, comprising mounting a semiconductor device on a wiring substrate obtained by the process for producing a wiring substrate according to claim 6.

8. Equipment for producing an adhesive sheet comprising a half-cutting apparatus, a cover film peeling apparatus, an adhesive tape applying apparatus, and an adhesive tape peeling apparatus in the order mentioned.

9. The process for producing an adhesive sheet having a singulated adhesive layer according to claim 2, wherein the adhesive tape has a carrier film (a′) and an adhesive layer (b′), the carrier film (a′) being made of a polyolefin.

10. The process for producing an adhesive sheet having a singulated adhesive layer according to claim 2, wherein the adhesive tape has a thickness of 10 to 40 μm.

11. The process for producing an adhesive sheet having a singulated adhesive layer according to claim 3, wherein the adhesive tape has a thickness of 10 to 40 μm.

12. The process for producing an adhesive sheet having a singulated adhesive layer according to claim 2, wherein in the peeling of the step D, a bending angle of the adhesive tape (θ1) and a bending angle of the carrier film (a) (θ2) satisfy the following expressions (I) and (II):

|θ1|<|θ2| (I)

|θ1|+|θ2|<60° (II).

13. The process for producing an adhesive sheet having a singulated adhesive layer according to claim 3, wherein in the peeling of the step D, a bending angle of the adhesive tape (θ1) and a bending angle of the carrier film (a) (θ2) satisfy the following expressions (I) and (II):

|θ1|<|θ2| (I)

|θ1|+|θ2|<60° (II).

14. The process for producing an adhesive sheet having a singulated adhesive layer according to claim 4, wherein in the peeling of the step D, a bending angle of the adhesive tape (θ1) and a bending angle of the carrier film (a) (θ2) satisfy the following expressions (I) and (II):

|θ1|<|θ2| (I)

|θ1|+|θ2|<60° (II).

15. A process for producing a wiring substrate, comprising:
aligning the surface on the side of the adhesive layer (b) of an adhesive sheet obtained by the production method according to claim 2 with the surface on the side of wiring of a wiring substrate, forming a laminate comprising the adhesive sheet and the wiring substrate by vacuum lamination or vacuum press, and then removing a carrier film (a) of the adhesive sheet.

16. A process for producing a wiring substrate, comprising:
aligning the surface on the side of the adhesive layer (b) of an adhesive sheet obtained by the production method according to claim 3 with the surface on the side of wiring of a wiring substrate, forming a laminate comprising the adhesive sheet and the wiring substrate by vacuum lamination or vacuum press, and then removing a carrier film (a) of the adhesive sheet.

17. A process for producing a wiring substrate, comprising:
aligning the surface on the side of the adhesive layer (b) of an adhesive sheet obtained by the production method according to claim 4 with the surface on the side of wiring of a wiring substrate, forming a laminate comprising the adhesive sheet and the wiring substrate by vacuum lamination or vacuum press, and then removing a carrier film (a) of the adhesive sheet.

18. A process for producing a wiring substrate, comprising:
aligning the surface on the side of the adhesive layer (b) of an adhesive sheet obtained by the production method according to claim 5 with the surface on the side of wiring of a wiring substrate, forming a laminate comprising the adhesive sheet and the wiring substrate by vacuum lamination or vacuum press, and then removing a carrier film (a) of the adhesive sheet.
